(19) United States
(12) Patent Application Publication
(10) Pub. No.: US 2010/0059747 A1
(43) Pub. Date: Mar. 11, 2010

(54) THIN FILM FIELD-EFFECT TRANSISTOR AND DISPLAY DEVICE

(75) Inventors: Masaya NAKAYAMA, Kanagawa (JP); Naoki KOITO, Kanagawa (JP)

Correspondence Address: Solaris Intellectual Property Group, PLLC, 401 Holland Lane, Suite 407, Alexandria, VA, 22314, US

(73) Assignee: FUJIFILM CORPORATION, Tokyo (JP)

(21) Appl. No.: 12/554,989

(22) Filed: Sep. 8, 2009

(30) Foreign Application Priority Data
Sep. 11, 2008 (JP) 2008-233724

(51) Int. Cl. H01L 29/786; H01L 33/00

(52) U.S. Cl. 257/43; 257/59; 257/E29.296; 257/E33.013

(57) ABSTRACT

The invention provides a thin film field-effect transistor including, on a substrate, a gate electrode, a gate insulating film, an active layer including an oxide semiconductor, a source electrode, a drain electrode, a resistive layer including an oxide semiconductor and positioned between the active layer and at least one of the source electrode or the drain electrode, the resistive layer having an electric conductivity that is lower than the electric conductivity of the active layer, the electric conductivity of the active layer being from 10⁻⁴ Scm⁻¹ to less than 10² Scm⁻¹, the ratio of the electric conductivity of the active layer to the electric conductivity of the resistive layer (electric conductivity of active layer/electric conductivity of resistive layer) being from 10¹ to 10¹⁰, and at least one of the source electrode or the drain electrode including a layer including Ti or a Ti alloy positioned at the side facing the resistive layer.

### CROSS-REFERENCE TO RELATED APPLICATION

This application claims priority under 35 USC 119 from Japanese Patent Application No. 2008-233724 filed Sep. 11, 2008, the disclosure of which is incorporated by reference herein.

### TECHNICAL FIELD

The present invention relates to a thin film field-effect transistor and a display device using the same. In particular, the invention relates to a thin film field-effect transistor that employs an amorphous oxide semiconductor in an active layer, and a display device using the same.

### BACKGROUND ART

In recent years, with developments in the technology of liquid crystals, electroluminescence (EL) or the like, flat panel display (FPD) devices have been put to practical use. In particular, organic electroluminescence devices (hereinafter, referred to as an organic EL device sometimes), which employs a thin film material that emits light when exited by the application of an electric current, are expected to achieve such effects as reduction in thickness, weight, size of the device, and reduction in power consumption of the device in a wide range of fields including cellular phone displays, personal digital assistants (PDA), computer displays, vehicle information displays, TV monitors, general illumination and the like, since these devices can emit light of high luminance at low voltage.

These FPDs are driven by an active matrix circuit of a thin film field-effect transistor (hereinafter, referred to as TFT sometimes) that employs an amorphous silicon thin film or a polycrystalline silicon thin film provided on a glass substrate as an active layer.

Meanwhile, in pursuance of further reduction in thickness or weight and improvement in breakage resistance of the FPDs, use of a light-weight and flexible resin substrate in place of a glass substrate has been attempted.

However, since the production of a TFT employing a silicon thin film as mentioned above includes a heating process at a relatively high temperature, it is difficult to form the silicon thin film directly on the resin substrate whose heat resistance is generally low.

In view of the above, TFTs in which an amorphous oxide such as an In—Ga—Zn—O amorphous oxide that can be formed into a layer at low temperature is used as a semiconductor thin film have been actively developed (for example, see Japanese Patent Application Laid-Open (JP-A) No. 2006-165529 and IDW/AD'05 (Dec. 6, 2005), pp. 845-846). Since the TFT employing an amorphous oxide semiconductor can be formed into a layer at room temperature, and can be formed on a film, these have attracted attention recently as a material for an active layer. In particular, Hosono et. al., Tokyo Institute of Technology, has reported that a TFT employing an amorphous InGaZnO₄ (a-IGZO) exhibits a field effect mobility of as high as about 10 cm²/Vs even on a PEN substrate, which is even higher than that of an a-Si type TFT formed on a glass substrate. Therefore, the TFT has attracted attention particularly as a film TFT (for example, see Nature, Vol. 432 (Nov. 25, 2004), pp. 488-492).

However, when a TFT employing a-IGZO is used for a drive circuit of a display device, for example, sufficient properties cannot be obtained by the mobility of 1 cm²/Vs to 10 cm²/Vs. Further, there are problems in that the off current is high and the on/off ratio is low. In particular, when such a TFT is used in a display device using an organic EL device, there is a demand for further improvements in mobility, on/off ratio and safety during driving. Among these characteristics, improvements in the threshold shift during driving the TFT are particularly desired.

Since a TFT using an amorphous oxide semiconductor can be formed into a film at room temperature, and can be produced using a flexible plastic film as a substrate, it has attracted attention as a material for an active layer of a film (flexible) TFT. In particular, JP-A No. 2006-165529 reports a TFT that is formed on a PET substrate and exhibits a field effect mobility of 10 cm²/Vs and an on/off ratio of 10³ or more, by employing an In—Ga—Zn—O oxide in a semiconductor layer (active layer). However, for example, when such a TFT is used for a driving circuit of a display device, sufficient properties for operating the driving circuit in terms of mobility and on-off ratio are yet to be achieved.

The reason for the above is that there has been a need to adjust the electronic carrier concentration in the active layer to a range of less than 10¹⁸/cm³ in conventional techniques in order to reduce the off current. Since the electronic mobility of the amorphous oxide semiconductor used in the active layer has a tendency to decrease as the electronic carrier concentration decreases, it has been difficult to form a TFT that exhibits favorable off characteristics and high mobility at the same time.

Further, during the development of a TFT using an amorphous oxide semiconductor, it has been found that a problem in that a voltage defined as a threshold voltage (Vth) as shown in FIG. 3 shifts to the higher side (threshold shift) may occur when the time for current application is increased. Therefore, from a practical application standpoint, solutions for this threshold shift are demanded.

### SUMMARY OF THE INVENTION

The present invention has been made in view of the above circumstances and provides a thin film field-effect transistor and a display device using the same.

An aspect of the invention provides a thin film field-effect transistor comprising a thin film field-effect transistor including, on a substrate, a gate electrode, a gate insulating film, an active layer including an oxide semiconductor, a source electrode, a drain electrode, a resistive layer including an oxide semiconductor and positioned between the active layer and at least one of the source electrode or the drain electrode, the resistive layer having an electric conductivity that is lower than the electric conductivity of the active layer, the electric conductivity of the active layer being from 10⁻⁴ Scm⁻¹ to less than 10² Scm⁻¹, the ratio of the electric conductivity of the active layer to the electric conductivity of the resistive layer (electric conductivity of active layer/electric conductivity of resistive layer) being from 10¹ to 10¹⁰, and at least one of the source electrode or the drain electrode including a layer including Ti or a Ti alloy positioned at the side facing the resistive layer.

### BRIEF DESCRIPTION OF THE DRAWINGS

Exemplary embodiments of the present invention will be described in detail based on the following figures, wherein:

FIG. 1 is a schematic view of an exemplary embodiment of the TFT device according to the invention;

FIG. 2 is a schematic view of another exemplary embodiment of the TFT device according to the invention;

FIG. 3 is a schematic view of an exemplary transmission characteristic curve showing a clear on/off ratio, where the horizontal axis refers to a gate voltage (Vg) and the vertical axis refers to an I_{DS} (drain-source current);

FIG. 4 is a conceptual view of an exemplary embodiment of drive TFT and organic EL device according to the invention; and

FIG. 5 is a schematic circuit diagram of the main part of switching TFT, drive TFT and organic EL device according to the invention.

### DETAILED DESCRIPTION OF THE INVENTION

1. Thin Film Field-Effect Transistor (TFT)

TFTs are an active device that includes at least a gate electrode, a gate insulation film, an active layer, a source electrode and a drain electrode in this order, and has a function of controlling a current that flows into the active layer upon application of a voltage to the gate electrode, and switching the current between the source electrode and the drain electrode. The TFT may have either a staggered structure or an inverted staggered structure.

The TFT of the present invention is an active device that includes, on a substrate, at least a gate electrode, a gate insulation film, an active layer including an oxide semiconductor, a source electrode, a drain electrode, and a resistive layer formed between the active layer and at least one of the source electrode or the drain electrode. Further, the electric conductivity of the active layer is 10⁻⁴ Scm⁻¹ or more and less than 10² Scm⁻¹, and the ratio of the electric conductivity of the active layer to the electric conductivity of the resistive layer (electric conductivity of active layer/electric conductivity of resistive layer) is from 10¹ to 10¹⁰. Moreover, at least one of the source electrode or a drain electrode includes a layer including Ti or a Ti alloy positioned at the side facing the resistive layer.

Preferably, both the source electrode and the drain electrode include a layer including Ti or a Ti alloy positioned at the side facing the resistive layer. The layer including Ti or a Ti alloy is preferably a Ti layer.

The ratio of the electric conductivity of the active layer to the electric conductivity of the resistive layer (electric conductivity of the active layer/electric conductivity of the resistive layer) is preferably from 10² to 10¹⁰, more preferably from 10² to 10⁸.

The electric conductivity of the active layer is preferably 10⁻¹ Scm⁻¹ or more and less than 10² Scm⁻¹.

The resistive layer preferably includes an oxide semiconductor.

The oxide semiconductor of the active layer is preferably an amorphous oxide.

The oxide semiconductor of the resistive layer is preferably an amorphous oxide.

The oxide semiconductor of the active layer or the resistive layer is preferably an oxide or a composite oxide of at least one selected from the group consisting of In, Ga and Zn. More preferably, the oxide semiconductor includes In and Zn, where the value of composition ratio of Zn and In (Zn/In) in the resistive layer is greater than the value of composition ratio of Zn/In in the active layer. Moreover, the value of Zn/In in the resistive layer is preferably greater than the value of Zn/In in the active layer by 3% or more, more preferably by 10% or more.

The active layer is preferably in contact with the gate insulating film. More preferably, the active layer is preferably in contact with the gate insulating film and the resistive layer is in contact with the source and drain electrodes.

In view of operation stability, the thickness of the resistive layer is preferably greater than the thickness of the active layer.

More preferably, the ratio of the thickness of the resistive layer to the thickness of the active layer (thickness of resistive layer/thickness of active layer) is greater than 1 and 100 or less, further preferably greater than 1 and 10 or less.

When the electric conductivity of the active layer is less than 10⁻⁴ Scm⁻¹, a high degree of mobility may not be obtained. When the electric conductivity of the active layer is 10² Scm⁻¹ or more, the amount of off current may increase and a favorable on/off ratio may not be obtained.

When the ratio of the electric conductivity of the active layer to the electric conductivity of the resistive layer (electric conductivity of active layer/electric conductivity of resistive layer) is less than 10¹, the on/off ratio may decrease. When the ratio of the electric conductivity of the active layer to the electric conductivity of the resistive layer exceeds 10¹⁰, stability of the TFT during a current test may decrease.

In another exemplary embodiment of the invention, the resistive layer and the active layer form a portion of an oxide semiconductor layer and the electric conductivity changes between the active layer and the resistive layer in a continuous manner. A structure in which the electric conductivity is higher at the side of gate insulating film while the electric conductivity is lower (highly resistive) at the side of source and drain electrodes is also preferred. In this case, for example, the active layer forms 10% of the oxide semiconductor layer at the side of gate insulating film, and the resistive layer forms 10% of the oxide semiconductor layer at the side of source and drain electrodes, with respect to the total thickness of the amorphous semiconductor layer, respectively.

The substrate is preferably a flexible resin substrate.

1) Structure

In the following, the configuration of the TFT according to the invention will be described.

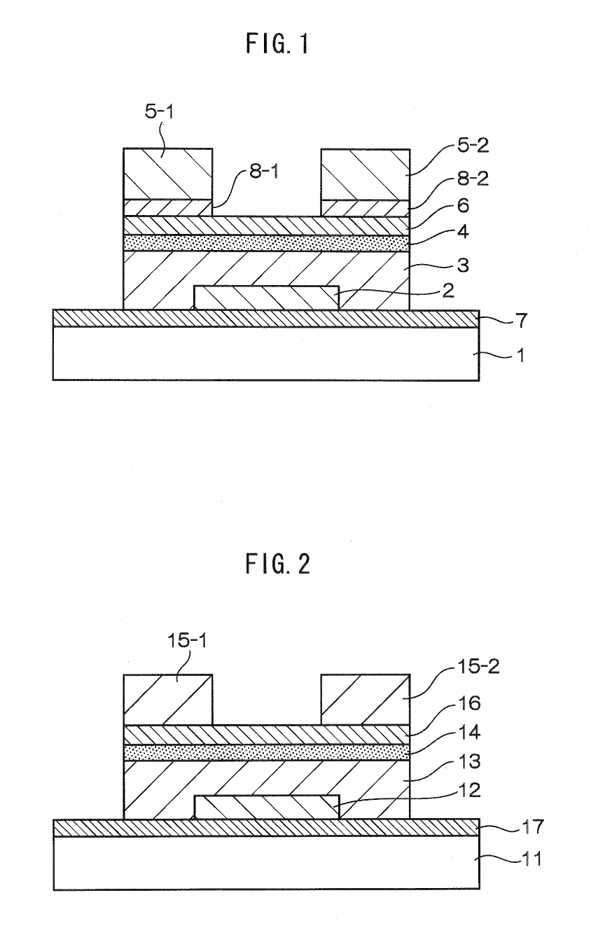

FIG. 1 is a schematic view of an example of the TFT of the invention having an inverted stagger structure. When a substrate 1 is a flexible substrate such as a plastic film, an insulation layer 7 is disposed on one surface of substrate 1, and a gate electrode 2, a gate insulation layer 3, an active layer 4, and a resistive layer 6 are formed thereon, and Ti or Ti alloy layers 8-1 and 8-2, a source electrode 5-1 and a drain electrode 5-2 are further formed thereon. In this structure, the Ti or Ti alloy layers form a portion of the source and drain electrodes.

In the above structure, a Ti or Ti alloy layers is formed at the side of the source and/or drain electrodes facing the resistive layer. The Ti or Ti alloy layer inhibits oxidization of the interface of the source and/or drain electrodes due to the resistive layer formed from an oxide semiconductor. When an oxide film is formed at the interface of the source and/or drain electrodes and the resistive layer, the contact resistance of the source and/or drain electrodes and the resistive layer may increase, or the electric resistivity of the resistive layer may also change. This may cause deterioration of TFT characteristics such as the threshold shift or reduction in mobility. By providing a Ti or Ti alloy layer to the source and/or drain electrodes at the side facing the resistive layer, a TFT that remains stable even during a prolonged driving can be obtained.

Active layer 4 is in contact with gate insulation film 3, and resistive layer 6 is positioned at the side of source electrode 5-1 and drain electrode 5-2, and is in contact with the Ti or Ti alloy layers. The composition of active layer 4 and resistive layer 6 is determined so that the electric conductivity of active layer 4 is greater than the electric conductivity of resistive layer 6, when no voltage is applied to the gate electrode. Active layer 4 may be formed from an oxide semiconductor as disclosed in JP-A No. 2006-165529, such as an In—Ga—Zn—O-based oxide semiconductor. It is known that the higher the concentration of electron carriers of these oxide semiconductors is, the higher the electron mobility of the same is. In other words, the higher the electric conductivity is, the higher the electron mobility is.

According to this structure of the invention, when the TFT is in an “on” state and a voltage is applied to the gate electrode, active layer 4 that serves as a channel exhibits a high degree of electric conductivity. Therefore, the field-effect mobility of the TFT is increased and a large amount of on-current can be obtained. On the other hand, when the TFT is in an “off” state, the off-current remains at a low level due to a small electric conductivity and a high degree of resistivity of resistive layer 6. Accordingly, the on-off ratio characteristics are remarkably improved.

In the conventional structure in which no resistive layer is provided, the carrier concentration of the active layer needs to be decreased in order to reduce the off current. JP-A 2006-165529 teaches that the electron carrier concentration needs to be controlled to be less than 10¹⁸/cm³, preferably less than 10¹⁶/cm³, in order to reduce the conductivity of the amorphous oxide semiconductor of the active layer so as to achieve a favorable on/off ratio. However, as shown in FIG. 2 of JP-A 2006-165529, when an In—Ga—Zn—O-based oxide semiconductor is used, electron mobility of the film is decreased as the electron carrier concentration is decreased.

Therefore, a field-effect mobility of 10 cm²/Vs or more may not be achieved and a sufficient on-current may not be obtained. As a result, sufficient on/off ratio characteristics may not be achieved.

Further, when the electron carrier concentration of the oxide semiconductor of the active layer is increased in order to increase the electron mobility of the film, the electric conductivity of the active layer may be increased and an off-current may be increased, thereby deteriorating the on/off ratio characteristics.

FIG. 2 is a schematic diagram showing another exemplary embodiment of the TFT according to the invention, in which active layer 14 and resistive layer 16 are formed on gate insulating film 13, and source and drain electrodes 15-1 and 15-2 formed from Ti are provided thereon. In this structure, the source and drain electrodes are formed from Ti.

2) Electric Conductivity

The electric conductivity is a value of a physical property which indicates a degree of electric conduction performed by a substance. The electric conductivity a of a substance can be expressed by the following formula, where the carrier concentration of the substance is denoted by n, the elementary charge is denoted by e, and the carrier mobility is denoted by μ.

σ=neμ

When the oxide semiconductor is an n-type semiconductor, electrons serve as the carrier. In this case, the carrier concentration refers to the concentration of electron carriers, and the carrier mobility refers to the electron mobility. Conversely, when the oxide semiconductor is a p-type semiconductor, electron holes serve as the carrier. In this case, the carrier concentration refers to the concentration of hole carriers, and the carrier mobility refers to the hole mobility. Further, the carrier concentration and the carrier mobility of a substance can be determined by Hall measurements.

<Method of Determining Electric Conductivity>

The electric conductivity of a film can be determined by measuring the sheet resistance of a film having a known thickness. The electric conductivity of a semiconductor changes depending on the temperature, and the electric conductivity cited herein refers to an electric conductivity at room temperature (20° C.).

3) Gate Insulation Film

An insulating material such as SiO₂, SiNₓ, SiON, Al₂O₃, Y₂O₃, Ta₂O₅, HfO₂or the like, or a mixed crystal compound including two or more of these compounds may be used for the gate insulation film. Further, a polymeric insulating material such as polyimide may also be used for the gate insulation film.

The thickness of the gate insulation film is preferably from 10 nm to 1000 nm. The gate insulation film needs to have a certain amount of thickness in order to reduce the amount of current leakage and enhance the voltage resistance. However, when the gate insulation film is too thick, the driving voltage of the TFT may be increased. Therefore, the thickness of the gate insulation film is preferably from 100 nm to 200 nm.

The thickness of a polymeric insulating film is preferably from 0.5 μm to 5 μm. It is particularly preferable to use an insulating material having a high degree of dielectric constant such as HfO₂ for the gate insulation film, since the TFT can be driven at low voltage.

4) Active Layer and Resistive Layer

The active layer and the resistive layer of the present invention are preferably formed from an oxide semiconductor. Among these, an amorphous oxide semiconductor is particularly preferred, since it can be formed into a film at low temperature and can be formed on a flexible resin substrate such as a plastic sheet. Examples of the preferable amorphous oxide semiconductors that can be processed at low temperature include those disclosed in JP-A No. 2006-165529, such as an oxide including In, an oxide including In and Zn, and an oxide including In, Ga and Zn. It is known that amorphous oxide semiconductors having a compositional structure of InGaO₃(ZnO)ₘ (m is a natural number less than 6) are preferable. These oxide semiconductors are an n-type semiconductor in which electrons serve as the carriers. Of course, p-type oxide semiconductors such as ZnO/Rh₂O₃, CuGaO₂, and SrCu₂O₂ may be used for the active layer or the resistive layer.

Specifically, the amorphous oxide semiconductor according to the invention preferably includes In—Ga—Zn—O, and more preferably has a composition of InGaO₃(ZnO)ₘ (m is a natural number less than 6) in a crystalline state, and InGaZnO₄ is particularly preferred. An amorphous oxide semiconductor having such a composition shows a tendency that the electron mobility increases as the electric conductivity increases. In addition, JP-A No. 2006-165529 discloses that the electric conductivity can be controlled by regulating the partial pressure of oxygen during the film formation.

Inorganic semiconductors such as Si and Ge, compound semiconductors such as GaAs, and organic semiconductor materials such as pentacene and polythiophene, carbon nanotubes, and the like, may also be used for the active layer or the resistive layer, in addition to oxide semiconductors.

<Electric Conductivity of Active Layer and Resistive Layer>

In the present invention, the active layer is formed in the vicinity of the gate insulating film, and the electric conductivity thereof is higher than the electric conductivity of the resistive layer that is formed in the vicinity of the source and drain electrodes.

The ratio of the electric conductivity of the active layer to the electric conductivity of the resistive layer (electric conductivity of active layer/electric conductivity of resistive layer) is preferably from 10¹ to 10¹⁰, more preferably from 10² to 10¹⁰, yet more preferably from 10² to 10⁸. The electric conductivity of the active layer is preferably 10⁻⁴ Scm⁻¹ or more and less than 10² Scm⁻¹, more preferably 10⁻¹ Scm⁻¹ or more and less than 10² Scm⁻¹.

The electric conductivity of the resistive layer is preferably 10⁻² Scm⁻¹ or less, more preferably 10⁻⁹ Scm⁻¹ or more and less than 10⁻³ Scm⁻¹.

<Thicknesses of Active Layer and Resistive Layer>

The thickness of the resistive layer is preferably greater than that of the active layer. More preferably, the value of the ratio of thickness of resistive layer/thickness of active layer is preferably greater than 1 and 100 or less, more preferably greater than 1 and 10 or less.

The thickness of the active layer is preferably 1 nm or more and 100 nm or less, more preferably 2.5 nm or more and 30 nm or less. The thickness of the resistive layer is preferably 5 nm or more and 500 nm or less, more preferably 10 nm or more and 100 nm or less.

When value of the ratio of thickness of resistive layer/thickness of active layer is 1 or less, favorable stability during driving may not be achieved, and when exceeds 100, mobility may decrease.

By employing the active layer and the resistive layer having the above structure, a TFT characteristic such as an on-off ratio of as high as 10⁶ or more can be achieved in a TFT having a mobility of as high as 10 cm²/V·sec or more.

<Means for Adjusting Electric Conductivity>

When the active layer and the resistive layer are composed of an oxide semiconductor, the following means can be used for adjusting the electric conductivity of the active layer and the resistive layer.

(1) Adjustment by Oxygen Defects

It is known that when oxygen defects are formed in an oxide semiconductor, carrier electrons are generated and the electric conductivity is increased. Hence, the electric conductivity of an oxide semiconductor can be controlled by adjusting the amount of oxygen defects. Specific methods of controlling the amount of oxygen defects include regulating the partial pressure of oxygen during film formation, regulating the oxygen concentration and the treatment time of the post-treatment after the film formation, and the like. Specific methods of the post-treatment include heating to a temperature of 100° C. or higher, using oxygen plasma, or using UV ozone. Among these, the method of controlling the partial pressure of oxygen during film formation is preferred in view of productivity. JP-A No. 2006-165529 discloses that the electric conductivity of an oxide semiconductor can be controlled by adjusting the partial pressure of oxygen during film formation, and this method can be applied to the present invention.

(2) Adjustment by Composition Ratio

It is known that the electric conductivity can be changed by changing the composition ratio of metals in an oxide semiconductor. For instance, JP-A No. 2006-165529 discloses that the electric conductivity is decreased as the concentration of Mg in InGaZn₁₋ₓMgₓO₄ is increased. In addition, it has been reported that in an oxide system of (In₂O₃)₁₋ₓ(ZnO)ₓ having a Zn/In ratio of 10% or higher, the electric conductivity is decreased as the concentration of Zn is increased (“TOMEI DOUDENMAKU NO SINTENKAI II (Developments of Transparent Conductive Films II)”, pages 34-35, CMC Publishing Co., Ltd.) As a specific means for changing the composition ratio, for example, when film formation is performed by sputtering, a method of using targets having different composition ratios may be used. Alternatively, the composition ratio of the layer may be changed by performing co-sputtering using multiple targets and regulating the sputtering ratios of the targets individually.

(3) Adjustment by Impurities

JP-A No. 2006-165529 discloses that by adding elements such as Li, Na, Mn, Ni, Pd, Cu, Cd, C, N and P to an oxide semiconductor as an impurity, the concentration of electron carriers can be reduced, and therefore the electric conductivity can be decreased. The addition of an impurity can be carried out by performing co-vapor deposition of the oxide semiconductor and the impurity, doping ions of the impurity element to an oxide semiconductor film which has been formed by an ion doping method, or the like.

(4) Adjustment by Oxide Semiconductor Material

In the above items (1) to (3), methods of adjusting the electric conductivity within the same oxide semiconductor system are described. However, it is also possible to change the electric conductivity by changing the type of oxide semiconductor material. It is known that SnO₂-based oxide semiconductors typically have lower electric conductivity than that of In₂O₃-based oxide semiconductors. Therefore, by changing the type of oxide semiconductor material, the electric conductivity can be adjusted. In particular, oxide insulating materials such as Al₂O₃, Ga₂O₃, ZrO₂, Y₂O₃, Ta₂O₃, MgO and HfO₃ are known as oxide materials having low electric conductivity.

The means stated in the above (1) to (4) may be employed independently or in combination.

<Method of Forming Active Layer and Resistive Layer>

The formation of the active layer and the resistive layer is preferably performed by a vapor-phase film forming method in which a polycrystalline sintered compact of an oxide semiconductor is used as a target. Among the vapor-phase film forming methods, a sputtering method and a pulsed laser deposition method (PLD method) are preferred, and a sputtering method is more preferred in terms of mass production.

For instance, the active layer can be formed by an RF magnetron sputtering deposition method while controlling the vacuum level and the flow rate of oxygen. The electric conductivity can be reduced by increasing the flow rate of oxygen.

Whether the obtained film is amorphous or not can be determined by a known X-ray diffraction method.

The thickness of the film can be determined by contact stylus-type surface profile measurement. The composition ratio can be determined by an RBS analysis (Rutherford Backscattering Spectrometry).

5) Ti or Ti Alloy Layer

The Ti or Ti alloy layer forms a portion of the source and/or drain electrodes, or forms the entire structure of the source and/or drain electrodes, and is positioned at the side facing the resistive layer.

The Ti or Ti alloy layer inhibits oxidation of the interface of source and/or drain electrodes due to the resistive layer formed from an oxide semiconductor. When an oxide film is formed at the interface of the resistive layer and the source and/or drain electrodes, the contact resistance of the resistive layer and the source and/or drain electrodes may increase, and the electric resistivity of the resistive layer may also change. This may result in degradation of the TFT characteristics such as threshold shift or mobility reduction. In the structure of the invention in which a Ti or Ti alloy layer is formed at the side facing the resistive layer, a TFT that remains stable even during a prolonged driving can be provided.

The Ti and Ti alloy used in the invention are pure titanium and an alloy of pure titanium and a metal of other kind, respectively. Many types of titanium alloy are known and the composition thereof is not particularly limited in the invention.

Examples of such alloys include alloys of Ti and Al, V, Mo, Sn, Fe, Cr, Zr, Nb, Mg or Ni. Specific examples of Ti alloys include an alloy having a composition of Ti-Al-V at a mass ratio of 90-6-4 or 74-4-22, and an alloy having a composition of Ti—Al—V—Sn at a mass ratio of 75-4-20-1.

The thickness of the Ti or Ti alloy layer is preferably from 1 to 200 nm, more preferably from 2 to 100 nm, and further preferably from 3 to 50 nm.

When the above thickness is less than 1 nm, the layer may not function to inhibit the oxidization of the interface between the resistive layer and the source and/or drain electrodes, while when the above thickness exceeds 200 nm, processing of the layer may be difficult.

The Ti or Ti alloy layer may form a portion of source electrode and/or drain electrodes, or the Ti or Ti alloy layer by itself may be the source electrode and/or the drain electrodes.

6) Gate Electrode

Preferable materials for the gate electrode according to the invention include metals such as Al, Mo, Cr, Ta, Ti, Au or Ag, alloys such as Al—Nd and APC; conductive films of a metal oxide such as tin oxide, zinc oxide, indium oxide, indium-tin oxide (ITO), or indium-zinc oxide (IZO); organic conductive compounds such as polyaniline, polythiophene, or polypyrrole; and combinations thereof. The thickness of the gate electrode is preferably from 10 nm to 1000 nm, more preferably from 20 to 500 nm, further preferably from 40 to 100 nm.

The method of forming the gate electrode is not particularly limited, and the electrode can be formed on the substrate according to a method that is appropriately selected in view of the characteristics of the material or the like, from the methods including a wet method such as a printing method and a coating method, a physical method such as a vacuum deposition method, a sputtering method and an ion plating method, a chemical methods such as a CVD method and a plasma CVD method, and the like. For example, when ITO is selected as the material, the gate electrode can be formed according to a DC or RF sputtering method, a vacuum deposition method, an ion plating method, or the like. Further, when an organic conductive compound is selected, the gate electrode can be formed according to a wet film-forming method or the like.

7) Source Electrode and Drain Electrode

The source electrode and the drain electrode may have a layered structure including a layer formed from a metal other than Ti and a layer formed from Ti or a Ti alloy, or may be entirely formed from a Ti or a Ti alloy layer.

Examples of the material for the layer that forms a layered structure with the Ti or a Ti alloy layer include metals such as Al, Mo, Cr, Ta, Ti, Au and Ag; alloys such as Al—Nd and APC; conductive films of metal oxides such as tin oxide, zinc oxide, indium oxide, indium-tin oxide (ITO) and indium-zinc oxide (IZO); and organic conductive compounds such as polyaniline, polythiophene and polypyrrole, and combinations thereof.

The thicknesses of the source electrode and the drain electrode are preferably from 10 nm to 1000 nm, more preferably from 20 to 500 nm, further preferably from 40 to 100 nm.

8) Substrate

The substrate used in the invention is not particularly limited, and may be formed from an inorganic material such as YSZ (yttria-stabilized zirconia) or glass, or an organic material such as synthetic resins including polyesters such as polyethylene terephthalate, polybutylene terephthalate and polyethylene naphthalate, polystyrene, polycarbonate, polyether sulfone, polyarylate, allyl diglycol carbonate, polyimide, polycycloolefin, norbornene resins, and polychlorotrifluoroethylene. The aforementioned organic materials preferably have superior heat resistance, dimension stability, solvent resistance, electric insulation property, proccessability, low gas permeability, low hygroscopicity, and the like.

In the present invention, a flexible substrate is particularly preferably used. Materials for the flexible substrate is preferably an organic plastic film having a high transmittance, including polyesters such as polyethylene terephthalate, polybutylene phthalate and polyethylene naphthalate, polystyrene, polycarbonate, polyether sulfone, polyarylate, polyimide, polycycloolefin, norbornene resins, polychlorotrifluoroethylene, and the like. It is also preferred to provide the film-shaped plastic substrate with an insulation layer (if the insulation property of the substrate is not sufficient), a gas-barrier layer for preventing penetration of moisture or oxygen, an undercoat layer for improving the planarity and the adhesion with respect to the electrode or the active layer of the substrate, or the like.

The thickness of the flexible substrate is preferably from 50 μm to 500 μm. When the thickness of the flexible substrate is less than 50 μm, it may be difficult to maintain a sufficient degree of planarity of the substrate, and when thickness of the flexible substrate is more than 500 μm, it may be difficult to freely bend the substrate itself, i.e., the flexibility of the substrate may not be sufficient.

9) Protective Insulation Film

As necessary, a protective insulation film may be provided on the TFT. The protective insulation film protects a semiconductor layer such as an active layer or a resistive layer from degradation due to air, or insulates an electronic device formed on the TFT from the TFT.

Specific examples of the material for the protective insulation film include metal oxides such as MgO, SiO, SiO₂, Al₂O₃, GeO, NiO, CaO, BaO, Fe₂O₃, Y₂O₃ and TiO₂, metal nitrides such as SiNₓ and SiNₓO_{y}, metal fluorides such as MgF₂, LiF, AlF₃ and CaF₂, polyethylene, polypropylene, polymethyl methacrylate, polyimide, polyurea, polytetrafluoroethylene, polychlorotrifluoroethylene, polydichlorodifluoroethylene, a copolymer of chlorotrifluoroethylene and dichlorodifluoroethylene, a copolymer obtained by copolymerizing a monomer mixture containing tetrafluoroethylene and at least one co-monomer, a fluorine-containing copolymer having a cyclic structure in a copolymerization main chain, a water-absorbing material having a water absorption of 1% or more, and a moisture-poof material having a water absorption of 0.1% or less.

The method of forming the protective insulation layer is not particularly limited, and may be selected from a vacuum deposition method, a sputtering method, a reactive sputtering method, an MBE (molecular beam epitaxy) method, a cluster ion beam method, an ion plating method, a plasma polymerization method (high-frequency excitation ion plating method), a plasma CVD method, a laser CVD method, a thermal CVD method, a gas source CVD method, a coating method, a printing method, a transfer method, or the like.

10) Post Treatment

As necessary, a thermal treatment may be conducted as a post treatment for the TFT. The thermal treatment is conducted at 100 ° C. or more in an atmospheric air or a nitrogen atmosphere. The thermal treatment may be conducted either after the formation of the semiconductor layer or after the production of the TFT. By performing the thermal treatment, effects such as suppressed in-plane irregularity of the TFT characteristics or improved driving stability can be achieved.

2. Display Device

The TFT according to the invention is suitably used in an image display device employing a liquid crystal or an EL device, especially in a flat panel display (FPD) device. More preferably, the TFT is used in a flexible display device using a flexible substrate such as an organic plastic film. In particular, the TFT according to the invention is most suitably used in an organic EL display device or a flexible organic EL device due to its high mobility.

3. Organic EL Device

The organic EL device according to the invention may include, other than a luminescent layer, a conventionally known organic compound layer such as a hole transport layer, an electron transport layer, a blocking layer, an electron injection layer and a hole injection layer.

1) Layer Structure

In the following, details of the layer structure will be described.

<Electrodes>

The organic EL layer according to the invention includes a pair of electrodes, and at least one of them is transparent and the other serves as a rear electrode. The rear electrode may be transparent or may not be transparent.

<Structure of Organic Compound Layer>

The structure of the organic compound layer as mentioned above is not particularly limited, and may be selected as appropriate according to applications. However, the organic compound layer is preferably formed on the aforementioned transparent electrode or the rear electrode. In this case, the organic compound layer is formed on both or either one of the transparent electrode or the rear electrode.

The shape, size or thickness of the organic compound layer is not particularly limited, and may be selected as appropriate according to applications.

Specific examples of the layer structure include the following, but the invention is not limited thereto.

(1) anode/hole transport layer/luminescent layer/electron transport layer/cathode

(2) anode/hole transport layer/luminescent layer/blocking layer/electron transport layer/cathode

(3) anode/hole transport layer/luminescent layer/blocking layer/electron transport layer/electron injection layer/cathode

(4) anode/hole injection layer/hole transport layer/luminescent layer/blocking layer/electron transport layer/cathode

(5) anode/hole injection layer/hole transport layer/luminescent layer/blocking layer/electron transport layer/electron injection layer/cathode

2) Hole Transport Layer

The hole transport layer that may be used in the invention includes a hole transport material. The hole transport material is not particularly limited as long as it has a function of transporting holes or a function of blocking electrons that are injected from the cathode. The hole transport material that may be used in the invention may be either a low-molecular hole transport material or a high-molecular hole transport material.

Specific examples of the hole transport material that may be used in the invention include carbazole derivatives, imidazole derivatives, polyarylalkane derivatives, pyrazoline derivatives, pyrazolone derivatives, phenylene diamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styryl amine compounds, aromatic dimethylidene compounds, porphyrin compounds, polysilane compounds, poly(N-vinylcarvazole) derivatives, aniline-based copolymers, thiophene oligomer, conductive polymeric oligomer such as polythiophene, and polymer compounds such as polyphenylene derivatives, polyphenylene vinylene derivatives and polyfluorene derivatives.

These compounds may be used alone or in combination of two or more kinds.

The thickness of the hole transport layer is preferably from 1 nm to 200 nm, more preferably from 5 nm to 100 nm.

3) Hole Injection Layer

In the invention, a hole injection layer may be provided between the hole transport layer and the anode.

The hole injection layer is a layer that facilitates injection of holes from the anode to the hole transport layer. Specifically, the hole injection layer is preferably formed from a material having a small ionization potential among the aforementioned hole transport materials, such as phthalocyanine compounds, porphyrin compounds, and starburst-type triarylamine compounds.

The thickness of the hole injection layer is preferably from 1 nm to 300 nm.

4) Luminescent Layer

The luminescent layer used in the invention includes at least one kind of luminescent material, and optionally a hole transport material, an electron transport material and a host material as necessary.

The luminescent material used in the invention is not particularly limited, and may be either a fluorescent material or a phosphorescent material. In view of the luminescent efficiency, a phosphorescent material is preferred.

Examples of the fluorescent material include metal complexes such as metal complexes or rare earth complexes of benzoxazole derivatives, benzimidazole derivatives, benzthiazole derivatives, styrylbenzene derivatives, polyphenyl derivatives, diphenyl butadiene derivatives, tetraphenyl butadiene derivatives, naphthalimide derivatives, coumarin derivatives, perylene derivatives, perinone derivatives, oxadiazole derivatives, aldazine derivatives, pyralizine derivatives, cyclopentadiene derivatives, bis(styrylanthacene) derivatives, quinacridone derivatives, pyrrolopyridine derivatives, thiadiazopyridine derivatives, styrylamine derivatives, aromatic dimethylidene compounds and 8-quinolinol derivatives, and polymer compounds such as polythiophene derivatives, polyphenylene derivatives, polyphenylenevinylene derivatives, and polyfluorene derivatives. These compounds may be used alone or in combination of two or more kinds.

The phosphorescent material is not particularly limited, but an ortho-metallized metal complex or a porphyrin metal complex are preferred.

The ortho-metallized metal complex is a collective name of a compound such as those described in, for example, Akio Yamamoto, “Organometallic Chemistry—Basic and Application”, pp. 150-232, Shokabo Publishing Co., Ltd. (1982) and H. Yersin, “Photochemistry and Photophysics of Coordination Compounds”, pp. 71-77 and pp. 135-146, published by Springer-Verlag. The use of an ortho-metallized metal complex as the luminescent material is advantageous in view of obtaining excellent luminance and luminescent efficiency.

There are many kinds of ligand that form an ortho-metallized metal complex, and some of these are described in the above literatures. Among these, 2-phenylpyridine derivatives, 7,8-benzquinoline derivatives, 2-(2-thienyl)pyridine derivatives, 2-(1-naphthyl)pyridine derivatives and 2-phenylquinoline derivatives are particularly preferred. The ortho-metallized metal complex may also have a ligand of other kind than the above.

The ortho-metallized metal complex that may be used in the invention may be synthesized by a known method, such as those described in Inorg. Chem., 1991, Vol. 30, p. 1685; Inorg. Chem., 1988, Vol. 27, p. 3464; Inorg. Chem., 1994, Vol. 33, p. 545; Inog. Chim. Acta, 1991, Vol. 181, p. 245; J. Organomet. Chem., 1987, Vol. 335, p. 293; and J. Am. Chem. Soc., 1985, Vol. 107, pp. 1431.

Among the above ortho-metallized complexes, compounds that emit light from triplet excitons are preferably used in the invention in view of improving luminescent efficiency.

Among the porphyrin metal complexes, a porphyrin platinum complex is preferred. The phosphorescent material may be used alone or in combination of two or more kinds. Further, a fluorescent material and a phosphorescent material may be used in combination.

The host material is a material having a function of causing energy migration from its exited state to a fluorescent material or a phosphorescent material, and as a result, allowing the fluorescent material or the phosphorescent material to emit light.

The host material is not particularly limited as long as it causes migration of energy from excitons to the luminescent material, and may be selected as appropriate according to usage. Specific examples thereof include metal complexes of carbazole derivatives, triazole derivatives, oxazole derivatives, oxadiazole derivatives, imidazole derivatives, polyarylalkane derivatives, pyrazoline derivatives, pyrazolone derivatives, phenylene diamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidene compounds, porphyrin compounds, anthraquinodimethane derivatives, anthrone derivatives, diphenylquinone derivatives, thiopyrane dioxide derivatives, carbodiimide derivatives, fluorenylidene methane derivatives, distyryl pyrazine derivatives, aromatic tetracarboxylic acid anhydrides such as naphthalene and perylene, phthalocyanine derivatives and 8-quinolinol derivatives, metal phthalocyanine, metal complex polysilane compound represented by metal complexes having benzoxazole or benzthiazole as a ligand, aniline-based copolymer, thiophene oligomer, conductive polymeric oligomer such as polythiophene, and polymer compounds such as polythiophene derivatives, polyphenylene derivatives, polyphenylenevinylene derivatives and polyfluorene derivatives. These compounds may be used alone or in combination of two or more kinds.

The content of the host material in the luminescent layer is preferably from 20 to 99.9% by mass, more preferably from 50 to 99.9% by mass.

5) Blocking Layer

In the invention, a blocking layer may be provided between the luminescent layer and the electron transport layer. The blocking layer is a layer that suppresses diffusion of excitons generated in the luminescent layer, or suppresses passage of holes to the cathode side.

The material for the blocking layer is not particularly limited as long as it receives electrons from the electron transport layer and passes them to the luminescent layer, and a typical electron transport material may be used. Examples of the material for the blocking layer include metal complexes of triazole derivatives, oxazole derivatives, oxadiazole derivatives, fluorenone derivatives, anthraquinodimethane derivatives, carbodiimide derivatives, fluorenylidene methane derivatives, distyrylpyradine derivatives, aromatic tetracarboxylic acid anhydrides such as naphthalene and perylene, phthalocyanine derivatives and 8-quinolinol derivatives, metal phthalocyanine, metal complexes having benzoxazole or benzthiazole as a ligand, aniline copolymers, thiophene oligomer, conductive polymeric oligomers such as polythiophene, and polymer compounds such as polythiophene derivative, polyphenylene derivative, polyphenylne vinylene derivative, and polyfluorene derivatives. These compounds may be used alone or in combination of two or more kinds.

6) Electron Transport Layer

In the invention, an electron transport layer including an electron transport material may be provided.

The electron transport material is not particularly limited as long as it has a function of transporting electrons or a function of blocking holes that have been injected from the anode, and may be selected from the electron transport materials as mentioned above that may be included in the blocking layer.

The thickness of the electron transport layer is preferably from 10 to 200 nm, more preferably from 20 to 80 nm.

When the above thickness exceeds 200 nm, the driving voltage may increase, while when the above thickness less than 10 nm, luminescent efficiency of the luminescent device may exceedingly decrease.

7) Electron Injection Layer

In the invention, an electron injection layer may be provided between the electron transport layer and the cathode.

The electron injection layer is a layer that facilitates injection of electrons from the cathode to the electron transport layer. Specifically, the layer may be formed using a lithium salt such as lithium fluoride, lithium chloride or lithium bromide, an alkali metal salt such as sodium fluoride, sodium chloride or cesium fluoride, or an insulating metal oxide such as lithium oxide, aluminum oxide, indium oxide or magnesium oxide.

The thickness of the electron injection layer is preferably from 0. 1 to 5 nm.

8) Substrate

The material for the substrate of an organic EL device is preferably a material that does not permeate moisture, or has an extremely low water permeability. Further, the material preferably does not scatter or attenuate light emitted from the organic compound layer. Specific examples thereof include inorganic materials such as YSZ (yttria-stabilized zirconia) or glass, organic materials including synthetic resins such as polyesters (e.g., polyethylene terephthalate, polybutylene tetephthalate and polyethylene naphthalate), polystylene, polycarbonate, polyether sulfone, polyarylate, allyldiglycol carbonate, polyimide, polycycloolefin, norbornene resin, and poly(chlorotrifluoroethylene).

The organic material as mentioned above preferably has sufficient heat resistance, dimension stability, solvent resistance, electric insulation property and proccessability, low air-permeability, and low moisture absorption. These materials may be used alone or in combination of two or more kinds.

The shape, structure, size or the like of the substrate is not particularly limited, and may be selected as appropriate according to applications. The substrate typically has a plate-like shape. The substrate may have a monolayer structure or a multilayer structure. Further, the substrate may be formed from a single member or formed from two or more members.

The substrate may be colorless and transparent, or colored and transparent. From the viewpoint of not scattering or attenuating light emitted from the luminescent layer, the substrate is preferably colorless and transparent.

The substrate preferably has a gas barrier layer on the front side or the rear side (the transparent electrode side). Preferable examples of the material for the gas barrier include an inorganic substance such as silicon nitride or silicon oxide. The gas barrier layer may be formed by, for example, a high-frequency sputtering method.

The substrate may further have a hardcoat layer or an undercoat layer, as necessary.

9) Electrode

Either of the electrodes used in the organic EL device may be an anode or a cathode, but preferably the first electrode is the anode, and the second electrode is the cathode.

<Anode>

The anode used in the organic EL device typically has a function of supplying holes to the organic compound layer as mentioned above. The shape, structure or size of the anode is not particularly limited, and may be selected as appropriate according to applications or usage of the luminescent device.

Preferable example of the material for the anode include metals, alloys, metal oxides, organic conductive compounds and a mixture thereof, and a material having a work function of 4.0 eV or more is preferred. Specific examples thereof include semiconductor-type metal oxides such as tin oxide doped with antimony, fluorine or the like (ATO, FTO and the like), tin oxide, zinc oxide, indium oxide, indium tin oxide (ITO), indium zinc oxide (IZO), metals such as gold, silver, chromium, nickel or the like, a mixture or a layered material of such a metal or a conductive metal oxide, copper iodide, copper sulfide or the like, organic conductive materials such as polyaniline, polythiophene, polypyrrole or the like, or a layered material of such an organic conductive material and ITO.

The anode may be formed on the substrate by a method as appropriately selected in view of suitability to the raw material for the anode, for example, a wet method such as printing or coating, a physical method such as vacuum evaporation, sputtering or ion plating, or a chemical method such as CVD or plasma CVD. For example, when ITO is selected as the raw material, the anode may be formed by direct-current or high-frequency sputtering, vacuum evaporation, ion plating or the like. When an organic conductive compound is used as the raw material, the anode may be formed by a wet film forming method.

The position of the anode in the luminescent device is not particularly limited, and may be selected as appropriate according to applications or usage of the luminescent device.

The patterning of the anode may be conducted by chemical etching such as photolithography, or by physical etching using laser beams. Further, the patterning may be conducted by performing vacuum evaporation or sputtering using a mask, a lift-off method, or a printing method.

The thickness of the anode is not particularly limited and may be selected as appropriate according to the type of the raw material, but is typically from 10 nm to 50 μm, preferably from 50 nm to 20 μm.

The resistivity of the anode is preferably 10³ Ω/square or less, more preferably 10² Ω/square or less.

The anode may be colorless and transparent, or colored and transparent. However, in order to take out light from the anode side, the transmittance of the anode is preferably 60% or more, more preferably 70% or more. This transmittance may be measured by a known method using a spectral photometer.

Details of the anode are described in “New Development of Transparent Electrode Film”, edited by Yutaka Sawada, published by CMC Publishing Co., Ltd. (1999), and these may be applied to the invention. When a plastic substrate having a low heat resistance is used, the anode may be formed from ITO or IZO at a temperature of as low as 150° C. or less.

<Cathode>

The cathode that may be used in the organic EL device typically has a function of injecting electrons to the organic compound layer as mentioned above. The shape, structure or size of the cathode is not particularly limited, and may be selected from known electrodes as appropriate according to applications or usage of the luminescent device.

Examples of the material for the cathode include metals, alloys, metal oxides, electroconductive compounds or a mixture thereof, and a material having a work function of 4.5 eV or less is preferred. Specific examples of the material include alkali metals (such as Li, Na, K and Cs), alkaline earth metals (such as Mg and Ca), gold, silver, lead, aluminum, sodium-potassium alloy, lithium-aluminum alloy, magnesium-silver alloy, indium, and rare earth metals such as ytterbium. These raw materials may be used alone, but preferably in combination of two or more kinds in view of achieving both stability and electron injection suitability.

Among the above, an alkali metal or an alkaline earth metal is preferred in view of electron injection suitability, while a material including aluminum as a main component is preferred in view of storage suitability. The material including aluminum as a main component refers to pure aluminum, or an alloy or a mixture of aluminum and 0.01 to 10% by mass of an alkali metal or an alkaline earth metal (such as lithium-aluminum alloy or magnesium-aluminum alloy).

Details of the material for the cathode are described in JP-A No. 2-15595 and JP-A No. 5-121172, and these may be applied to the invention.

The formation of the cathode is not particularly limited, and may be formed on the substrate by a known method. For example, the cathode may be formed on the substrate by a method selected as appropriate according to the suitability for its material, including a wet method such as printing or coating, a physical method such as vacuum evaporation, sputtering or ion plating, or a chemical method such as CVD or plasma CVD.

For example, when the cathode is formed from a metal or the like, one or more kinds of the metal may be deposited by performing sputtering, simultaneously or separately.

The patterning of the cathode may be conducted by chemical etching such as photolithography, or by physical etching using laser beams. Alternatively, the cathode may be formed by vacuum evaporation or sputtering using a mask, a lift-off method, or a printing method.

The position of the cathode in the organic EL device is not particularly limited, and may be selected as appropriate according to applications or usage of the luminescent device. However, the cathode is preferably formed on the organic compound layer. In this case, the cathode may be formed on the entire surface of the organic compound layer, or may be formed on a portion of the organic compound layer.

Further, a dielectric layer having a thickness of from 0.1 to 5 nm formed of a fluoride of an alkali metal or an alkaline earth metal as mentioned above may be provided between the cathode and the organic compound layer.

The thickness of the cathode is not particularly limited and may be selected as appropriate according to the type of raw material, but is typically from 10 nm to 50 μm, preferably from 20 nm to 500 nm.

The cathode may be transparent or not transparent. When a transparent cathode is desired, it can be obtained by forming a thin film having a thickness of from 1 to 10 nm from the raw material for the cathode as mentioned above, and then forming a layer of a transparent conductive material such as ITO or IZO on the above thin film.

10) The Entire Structure of the Organic EL Device may be Protected by a Protection Layer.

The material that may be included in the protection layer is not particularly limited as long as it has a function of suppressing moisture, oxygen or the like that promotes deterioration of the device from entering the device.

Specific examples of the material include metals such as In, Sn, Pb, Au, Cu, Al, Ti or Ni, metal oxides such as MgO, SiO, SiO₂, Al₂O₃, GeO, NiO, CaO, BaO, Fe₂O₃, Y₂O₃ or TiO₂, metal nitrides such as SiNₓ or SiNₓO_{y}, metal fluorides such as MgF₂, LiF, AlF₃ or CaF₂, polyethylene, polypropylene, polymethyl methacrylate, polyimide, polyurea, polytetrafluoroethylene, polychlorotrifluoroethylene, polydichlorodifluoroethylene, copolymer of chlorotrifluoroethylene and dichlorodifluoroethylene, copolymers obtained by copolymerizing a monomer mixture including tetrafluoroethylene and at least one kind of comonomer, fluorine-containing copolymers having a cyclic structure in a copolymer main chain, water-absorbing materials having a water absorption of 1% or more, and moisture-proof materials having a water absorption of 0.1% or less.

The method of forming the protection layer is not particularly limited, and may be conducted by a vacuum evaporation method, a sputtering method, a reactive sputtering method, a MBE (Molecular Beam Epitaxy) method, a cluster ion beam method, an ion plating method, a plasma polymerization method (high-frequency exited ion plating method), a plasma CVD method, a laser CVD method, a thermal CVD method, a gas source CVD method, a coating method, a printing method, a transfer method, or the like.

11) Sealing

The entire structure of organic EL device may be sealed using a sealing container. Further, a water absorbing material or an inert liquid may be included in a space between the sealing container and the luminescent device.

The water absorbing material is not particularly limited, and examples thereof include barium oxide, sodium oxide, potassium oxide, calcium oxide, sodium sulfate, calcium sulfate, magnesium sulfate, phosphorus pentoxide, calcium chloride, magnesium chloride, copper chloride, cesium fluoride, niobium fluoride, calcium bromide, vanadium bromide, molecular sieve, zeolite, and magnesium oxide.

The inert liquid is not particularly limited, and examples thereof include paraffins, fluid paraffins, fluorine-based solvents such as perfluoroalkane, perfluoroamine and perfluoroether, chlorine-based solvents, and silicone oils.

12) Production Method of the Device

Each layer of the organic EL device may be suitably formed by either a dry method such as evaporation or sputtering or a wet method such as dipping, spin coating, dip coating, casting, die coating, roll coating, bar coating, or gravure coating.

Among these, a dry method is preferred in view of luminescent efficiency or durability. When the layer is formed by a wet method, the remaining coating solvent may damage the luminescent layer.

In particular, a resistance heating vacuum evaporation method is preferred since only a substance to be evaporated under vacuum can be heated with high efficiency, thereby reducing damages to the device caused by exposing the device to high temperature.

The vacuum evaporation is a technique in which a material to be evaporated is heated to cause vaporization or sublimation in a vacuum container, and the vaporized or sublimated material is attached to an object placed at a certain distance to form a thin film on the object. The heating may be conducted by means of resistance heating, electron beams, high-frequency induction, laser beams, or the like. Among these, the resistant heating enables formation of a film at the lowest temperature. Therefore, unless the material has a sublimation point that is too high to conduct evaporation, a film can be formed without causing substantial damages to the object due to heating.

The sealing film according to the invention can be formed by resistance heating vacuum evaporation.

The sealing material such as silicon oxide that has been conventionally used and has a high sublimation point cannot be evaporated by resistance heating. On the other hand, in vacuum evaporation methods as generally described in known techniques, such as an ion plating method, the temperature at an evaporation base portion reaches an extremely high level of several thousand degrees C, thereby denaturing the object by causing damages due to heat. Therefore, these methods are not suitable for the formation of a sealing film for an organic EL device that is particularly vulnerable to heat or UV rays.

13) Driving Method

The organic EL device can be driven to emit light by applying a direct voltage (an alternating component may be included as necessary) of typically from 2 to 15V between the anode and the cathode.

The driving method of organic EL device may be those described in JP-A No. 2-148687, JP-A No. 6-301355, JP-A No. 5-29080, JP-A No. 7-134558, JP-A No. 8-234685, JP-A No. 8-241047, Japanese Pat. No. 2,784,615, U.S. Pat. No. 5,828,429, and U.S. Pat. No. 6,023,308.

(Applications)

The TFT according to the invention is applicable to an image display device using a liquid crystal or an EL device, a switching device or a driving device of a FPD, or the like. In particular, the TFT according to the invention is suitable used as a switching device or a driving device of a flexible FPD. Further, the display device using the TFT according to the invention is applicable for a wide range of fields including a display for a cellular phone, a personal digital assistant (PDA), a computer display, an information display for an automobile, a TV monitor, and typical illuminating devices.

Further, the TFT according to the invention is applicable to an IC card or an ID tag in which the TFT is formed on a flexible substrate such as an organic plastic film.

The following are exemplary embodiments of the invention. However, the invention is not limited thereto.
<1> A thin film field-effect transistor comprising, on a substrate, a gate electrode, a gate insulating film, an active layer comprising an oxide semiconductor, a source electrode, a drain electrode, a resistive layer comprising an oxide semiconductor and positioned between the active layer and at least one of the source electrode or the drain electrode, the resistive layer having an electric conductivity that is lower than the electric conductivity of the active layer, the electric conductivity of the active layer being from 10⁻⁴ Scm⁻¹ to less than 10² Scm⁻¹, the ratio of the electric conductivity of the active layer to the electric conductivity of the resistive layer (electric conductivity of active layer/electric conductivity of resistive layer) being from 10¹ to 10¹⁰, and at least one of the source electrode or the drain electrode comprising a layer comprising Ti or a Ti alloy positioned at the side facing the resistive layer.
<2> The thin film field-effect transistor according to <1>, wherein the active layer is in contact with the gate insulating film.
<3> The thin film field-effect transistor according to <1>, wherein the ratio of the electric conductivity of the active layer to the electric conductivity of the resistive layer (electric conductivity of active layer/electric conductivity of resistive layer) is from 10² to 10¹⁰.
<4> The thin film field-effect transistor according to <3>, wherein the ratio of the electric conductivity of the active layer to the electric conductivity of the resistive layer (electric conductivity of active layer/electric conductivity of resistive layer) is from 10² to 10⁸.
<5> The thin film field-effect transistor according to <1>, wherein the source electrode and the drain electrode include the layer comprising Ti or a Ti alloy positioned at the side facing the resistive layer.
<6> The thin film field-effect transistor according to <1>, wherein the electric conductivity of the active layer is from 10⁻¹ Scm⁻¹ to less than 10² Scm⁻¹.
<7> The thin film field-effect transistor according to <1>, wherein at least one of the oxide semiconductor of the active layer or the oxide semiconductor of the resistive layer comprises an amorphous oxide.
<8> The thin film field-effect transistor according to <1>, wherein at least one of the oxide semiconductor of the active layer or the oxide semiconductor of the resistive layer comprises an oxide or a composite oxide of at least one selected from the group consisting of In, Ga and Zn.
<9> The thin film field-effect transistor according to <1>, wherein the substrate comprises a flexible resin substrate.
<10> A display device comprising the thin film field-effect transistor according to <1>.

### EXAMPLES

Hereinafter, the thin film field effect transistor of the invention will be described according to Examples, but the invention is not limited thereto.

### Example 1

1. Production of TFT Device

A TFT device having a structure equivalent to FIG. 1 or FIG. 2 was produced using an alkali-free glass plate (product number: 1737, product of Corning, Inc.) as a substrate, and the following layers were formed thereon in the following order.

(1) Gate electrode: Mo was vapor-deposited to a thickness of 40 nm.

Sputtering conditions: The sputtering was performed using a DC magnetron sputtering device at a DC power of 380 W and a sputtering gas (Ar) flow rate of 12 sccm.

The patterning of the gate electrode was conducted by a photolithography method and an etching method.

(2) Gate insulating film: A film of SiO₂ having a thickness of 200 nm was formed using an RF magnetron sputtering vacuum deposition method (target: SiO₂, film formation temperature: 54° C., sputtering gas (Ar/O₂) flow rate: 12/2 sccm, RF power: 400 W, film formation pressure: 0.4 Pa).

(3) Active Layer and Resistive Layer

On the gate insulating film, an active layer was formed in accordance with the following Conditions 1 or 3, and a resistive layer was formed in accordance with the following Condition 2. The TFT device No., the selected conditions, and the thickness of the thus formed layer are shown in Table 1.

<Conditions 1>

Film formation was performed using a polycrystal sintered compact having a composition of InGaZnO₄ as a target, by an RF magnetron sputtering vacuum deposition method (Ar flow rate: 97 sccm, O₂ flow rate: 0.8 sccm, RF power: 200 W, pressure: 0.38 Pa).

<Conditions 2>

Film formation was performed in a similar manner to Conditions 1, except that the O₂ flow rate was 2.0 sccm.

<Conditions 3>

Film formation was performed in a similar manner to Conditions 1, except that the O₂ flow rate was 1.6 sccm.

(4) Source Electrode and Drain Electrode

A source electrode and a drain electrode having different compositions were formed on the resistive layer or the active layer under the following conditions.

The patterning of the source electrode and the drain electrode was performed by a photolithography method and a lift-off method.

Source Electrode and Drain Electrode (A)

Ti was vapor-deposited to a thickness of 50 nm by DC magnetron sputtering (DC power: 400 W, Ar flow rate: 13 sccm, pressure: 0.34 Pa).

Source Electrode and Drain Electrode (B)

Al was vapor-deposited to a thickness of 50 nm by DC magnetron sputtering (DC power: 400 W, Ar flow rate: 13 sccm, pressure: 0.34 Pa).

Source Electrode and Drain Electrode (C)

A source electrode and a drain electrode have a three-layer structure of Ti/Al/Ti were formed.

First layer: Ti was vapor-deposited to a thickness of 10 nm under the same conditions as the source electrode and the drain electrode (A).

Second layer: Al was vapor-deposited to a thickness of 30 nm on the first layer under the same conditions as the source electrode and the drain electrode (B).

Third layer: Ti was vapor-deposited to have a thickness of 10 nm on the second layer under the same conditions as the source electrode and the drain electrode (A).

Source Electrodes and Drain Electrodes (D) to (I)

ITO, Mo, Ag, Au, Cr, and Cu were vapor-deposited to a thickness of 50 nm under the same conditions as in the source electrode and the drain electrode (B), respectively.

2. Measurement of Film Properties

An oxide semiconductor layer was formed on an alkali-free glass substrate (product number: 1737, product of Corning, Inc.) in accordance with the Conditions 1 to 3 as described above, under the same production conditions as in the TFT devices as described above, thereby preparing samples for measurement of film properties. The thickness of the obtained samples was 100 nm. The electric conductivity of these samples was measured.

—Method of Measuring Electric Conductivity—

The electric conductivity of the samples was calculated from the sheet resistance and the film thickness of the samples. When the sheet resistance is defined as ρ (Ω/square) and the film thickness is defined as d (cm), the electric conductivity σ (Scm⁻¹) is determined as σ=1/(ρ*d).

In this Example, the measurement was performed at 20° C. using a LORESTA-GP (manufactured by Mitsubishi Chemical Analytech Co., Ltd.) in a region where the sheet resistance of the sample is lower than 10⁷ Ω/square, while the measurement was conducted at 20° C. using a HIRESTA-UP (manufactured by Mitsubishi Chemical Analytech Co., Ltd.) in a region where the sheet resistance of the sample is 10⁷ Ω/square or more. The thickness of the samples was measured using a stylus surface profiler DEKTAK-6M (manufactured by ULVAC, Inc.)

—Method of Measuring Composition Ratio—

The composition ratio of the samples was determined by RBS (Rutherford back scattering) analysis. Further, it was confirmed that each sample was an amorphous film by the analysis using a known X-ray diffraction method.

The structure and the physical property values of the TFT devices are shown in Table 1.

TABLE 1

| | | | | | | | | Source and drain | |
|---|---|---|---|---|---|---|---|---|---|
| | Active layer | | | Resistive layer | | | Electrical | electrodes | |
| | Film | Thick- | Electrical | Film | | Electrical | conductivity | | Composition, |
| | formation | ness | conductivity | formation | Thickness | conductivity | ratio | Layer | Thickness |
| TFT device No. | conditions | (nm) | (Scm⁻¹) (a) | conditions | (nm) | (Scm⁻¹) (b) | (a)/(b) | No. | (nm) |
| TFT of Invention 1 | Conditions 1 | 10 | 2.3 × 10¹ | Conditions 2 | 40 | 6.6 × 10⁻⁶ | 3.5 × 10⁶ | A | Ti (50 nm) |
| TFT of Invention 2 | Conditions 1 | 10 | 2.8 × 10¹ | Conditions 2 | 40 | 5.8 × 10⁻⁶ | 4.8 × 10⁶ | C | Ti/Al/Ti |
| | | | | | | | | | (10 nm/30 nm/ |
| | | | | | | | | | 10 nm) |
| Comparative TFT 1 | Conditions 1 | 10 | 2.8 × 10¹ | Conditions 2 | 40 | 6.8 × 10⁻⁶ | 4.1 × 10⁶ | D | ITO (50 nm) |
| Comparative TFT 2 | Conditions 3 | 50 | 1.1 × 10⁻⁴ | — | — | — | — | A | Ti (50 nm) |
| Comparative TFT 3 | Conditions 3 | 50 | 1.6 × 10⁻⁴ | — | — | — | — | D | ITO (50 nm) |
| Comparative TFT 4 | Conditions 1 | 10 | 2.4 × 10¹ | Conditions 2 | 40 | 5.4 × 10⁻⁶ | 4.4 × 10⁶ | B | Al (50 nm) |
| Comparative TFT 5 | Conditions 1 | 10 | 2.6 × 10¹ | Conditions 2 | 40 | 5.8 × 10⁻⁶ | 4.5 × 10⁶ | E | Mo (50 nm) |
| Comparative TFT 6 | Conditions 1 | 10 | 2.8 × 10¹ | Conditions 2 | 40 | 6.0 × 10⁻⁶ | 4.7 × 10⁶ | F | Ag (50 nm) |
| Comparative TFT 7 | Conditions 1 | 10 | 2.4 × 10¹ | Conditions 2 | 40 | 6.2 × 10⁻⁶ | 3.9 × 10⁶ | G | Au (50 nm) |
| Comparative TFT 8 | Conditions 1 | 10 | 3.0 × 10¹ | Conditions 2 | 40 | 6.6 × 10⁻⁶ | 4.6 × 10⁶ | H | Cr (50 nm) |
| Comparative TFT 9 | Conditions 1 | 10 | 2.6 × 10¹ | Conditions 2 | 40 | 6.2 × 10⁻⁶ | 4.2 × 10⁶ | I | Cu (50 nm) |

3. Performance Evaluation

1) Evaluation Method

The TFT device having a channel length L of 40 μm and a channel width W of 200 μm was used for the evaluation.

Transfer characteristics of each TFT device was measured at a saturation region drain voltage Vd of 10 V (gate voltage: −10 V≦Vg≦15 V). The measurement was conducted using a semiconductor parameter analyzer 4156C (manufactured by Agilent Technologies).

—Calculation of On/Off Ratio—

The on/off ratio is determined from a ratio of a maximum value of drain current (Id)ₘₐₓ to a minimum value of drain current (Idₘᵢₙ) from the TFT transfer characteristics (Idₘₐₓ/Idₘᵢₙ).

—Measurement of Field Effect Mobility—

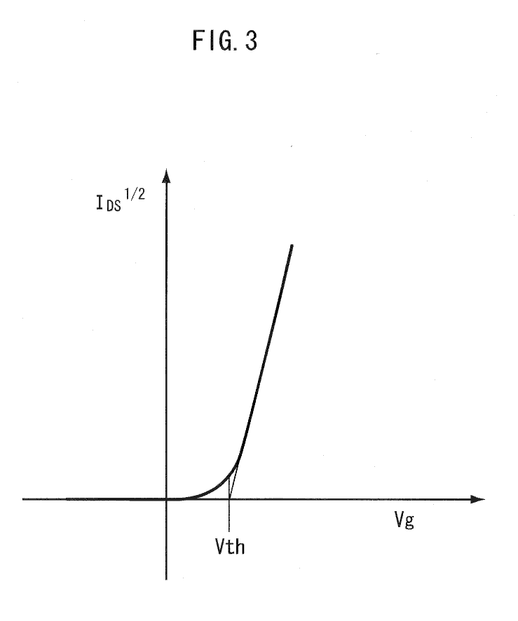

As schematically shown in FIG. 3, a drain-source current (I_{DS}) is obtained as a function of a gate-source voltage (V_{GS}), and then a threshold voltage (Vth) is determined from the obtained curve. In this case, the drain-source voltage (V_{DS}) was fixed to 10 V while the V_{GS} was changed from −10 V to +15 V. The threshold voltage and the field effect mobility were extracted from a (I_{DS})^{1/2} VS. (V_{GS}) curve, using the following equation.

I_{DS}=μ_{FE}·C_{dielectric}·(W/2L)−(V_{GS}−Vₜₕ)²

In the above equation, μ_{FE} represents a field effect mobility, Vₜₕ represents a threshold voltage, W represents a channel width, L represents a channel length, and C_{dielectric} represents a gate insulating film dielectric capacity.

—Threshold Shift Amount—

A stress was applied to each TFT device by diode connection for 10 hours so that a stress current I_{DS} was 3 μA. The amount of change in the threshold before and after the application of the stress is defined as a threshold shift amount (V), and evaluation was performed.

The obtained results are shown in Table 2.

TABLE 2

| | Device performance | | | |
|---|---|---|---|---|
| | | | | Threshold |
| | | | | shift |
| | | | Threshold | amount |
| | Mobility | | value (Vth) | (ΔVth) |
| TFT device No. | (cm²/Vs) | on/off ratio | (V) | (V) |
| TFT of Invention 1 | 26.4 | 1.2 × 10⁷ | 0.6 | 0.4 |
| TFT of Invention 2 | 26.6 | 1.2 × 10⁷ | 0.6 | 0.2 |
| Comparative TFT 1 | 16.5 | 3.0 × 10⁶ | 1.0 | 1.0 |
| Comparative TFT 2 | 4.2 | 9.0 × 10⁵ | 0.8 | 4.2 |
| Comparative TFT 3 | 4.3 | 9.0 × 10⁵ | 1.2 | 3.8 |
| Comparative TFT 4 | 15.3 | 2.4 × 10⁶ | 1.2 | 3.6 |
| Comparative TFT 5 | 24.1 | 1.0 × 10⁷ | 0.8 | 1.2 |
| Comparative TFT 6 | 16.6 | 2.1 × 10⁶ | 0.8 | 2.8 |
| Comparative TFT 7 | 10.8 | 9.0 × 10⁵ | 1.4 | 2.6 |
| Comparative TFT 8 | 12.4 | 2.1 × 10⁶ | 1.2 | 4.2 |
| Comparative TFT 9 | 18.4 | 2.1 × 10⁶ | 1.0 | 2.8 |

TFT devices 1 and 2 of the invention exhibited a high degree of mobility and a high degree of on/off ratio. Furthermore, the amount of threshold shift was small and stable performances were exhibited.

In contrast, comparative TFT devices 2 and 3 having no resistive layer exhibited a low degree of mobility and a low degree of on/off ratio, and a large amount of threshold shift.

Comparative TFT device 5 exhibited a mobility equivalent to that of the TFT device of the invention, but the amount of threshold shift was large and the stability was poor.

Comparative TFT devices 1, 4 and 6 to 9 exhibited a mobility and an on/off ratio that were inferior to that of TFT devices of the invention. Further, the amount of threshold shift was large and the stability was poor.

### Example 2

1. Production of TFT Device of Invention 10

TFT device of the invention 10 was produced in a substantially similar manner to the production of TFT device of the invention 1, except that a polyethylenenaphthalate film having an insulating layer having a barrier function as described below on both sides was used as the substrate.

Insulating layer: SiON was vapor-deposited to a thickness of 500 nm. The vapor-deposition of SiON was performed by an RF magnetron sputtering vacuum deposition method (target: Si₃N₄, RF power: 400 W, gas flow rate (Ar/O₂): 12/3 sccm, film formation pressure: 0.45 Pa).

2. Performance Evaluation

The performances of TFT device 10 were evaluated in a similar manner to Example 1. As a result, TFT device 10 exhibited equivalent levels of electric field mobility and on/off ratio to that of TFT device 1 formed on a glass substrate. Accordingly, the TFT device of the invention exhibits a high degree of mobility and a high degree of on/off ratio even when formed on a flexible substrate of an organic plastic film, and exhibits a small amount of threshold shift.

### Example 3

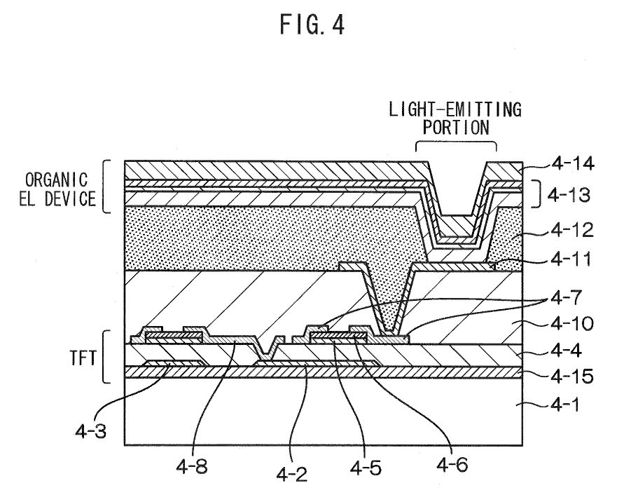

An organic EL display having the structure shown in FIG. 4 was produced.

1) Formation of Substrate Insulating Film

A substrate insulating film 4-15 was formed on a polyethylenenaphthalate (PEN) film 4-1 by vapor-depositing SiON by sputtering to a thickness of 50 nm.

The sputtering was performed using Si₃N₄ as a target with an RF magnetron sputtering device (RF power: 400 W, sputtering gas flow rate (Ar/O₂): 12.0/3.0 sccm, film forming pressure: 0.4 Pa).

2) Formation of Gate Electrode (and Scanning Wires)

After cleaning the substrate, Mo was vapor-deposited thereon to a thickness of 100 nm by sputtering. Then, a photoresist was applied to the substrate and a photomask was placed thereon. The substrate was exposed to light through the photomask and heated to cure an unexposed portion of the photoresist. Then, an uncured portion of the photoresist was removed by a subsequent treatment using an alkaline developer. Next, an electrode portion at a portion that is not covered with the cured photoresist was dissolved using an etching liquid, and was then removed. Finally, the photoresist was removed and the patterning process was completed. A patterned gate electrode 4-2 and a scanning wire 4-3 were thus formed.

The conditions for each step of the above process are as follows.

Mo sputtering: the sputtering was performed using a DC magnetron sputtering device (DC power: 380 W, sputtering gas flow rate (Ar): 14 sccm, film forming pressure: 0.34 Pa).

Photoresist application: A photoresist OFPR-800 (trade name, Tokyo Ohka Kogyo Co., Ltd.) was applied by spin coating at 4000 rpm for 50 sec. Pre-baking was performed at 80° C. for 20 min.

Exposure to light: The exposure was conducted for 5 sec. using g-line rays of an extra high pressure mercury lamp, equivalent to 100 mJ/cm².

Development: Developer: NMD-3 (trade name, manufactured by Tokyo Ohka Kogyo Co., Ltd.): 30 sec. (immersion)+30 sec. (stirring)

Rinse: Pure-water ultrasonic cleaning, 1 min. (twice)

Post baking: 120° C. for 30 min.

Etching: Etching liquid: mixed acid (nitric acid/phosphoric acid/acetic acid)

Removal of Resist: Removing liquid: 104 (manufactured by TOKYO OHKA KOGYO CO., LTD.), 5 min. (immersion) twice

Cleaning: IPA ultrasonic cleaning for 5 min. (twice) and pure-water ultrasonic cleaning for 5 min.

Drying: N₂ blowing and baking at 120° C. for 1 h.

3) Formation of Gate Insulating Film

A gate insulating film 4-4 was formed from SiO₂ to a thickness of 200 nm by sputtering.

Sputtering conditions: The sputtering was performed using an RF magnetron sputtering device (RF power: 400 W, sputtering gas flow rate (Ar/O₂): 12.0/2.0 sccm, and a film formation pressure: 0.4 Pa).

4) Formation of Active Layer and Resistive Layer

An IZGO film having a thickness of 10 nm for active layer 4-5 and an IZGO film having a thickness of 40 nm for resistive layer 4-6 were formed on the gate insulating film by sputtering, respectively. Subsequently, patterning was performed by a photoresist method, thereby forming the active layer and the resistive layer.

The sputtering conditions of the IZGO film for the active layer and the IZGO film for the resistive layer are as follows.

Sputtering conditions of the IZGO film of the active layer: The sputtering was performed using a polycrystal sintered compact having a composition of InGaZnO₄ as a target, with an RF magnetron sputtering device (RF power: 200 W, sputtering gas flow rate (Ar/O₂): 97.0/0.8 sccm, and film formation pressure: 0.36 Pa).

Sputtering conditions of the IZGO film of the resistive layer: The sputtering was performed using a polycrystal sintered compact having a composition of InGaZnO₄ as a target, with an RF magnetron sputtering device (RF power: 200 W, sputtering gas flow rate: (Ar/O₂): 97.0/2.0 sccm, and film formation pressure: 0.38 Pa).

The patterning process by a photolitho-etching method was performed in a similar manner to the patterning process for the gate electrode, except that oxalic acid was used as the etching liquid.

5) Formation of Contact Hole H1

Subsequently, a patterning process by a photolitho-etching method was performed in a similar manner to the patterning process of the gate electrode, and a portion other than a portion for forming a contact hole was protected by a photoresist. Then, a hole was formed in the gate insulating film using a buffered fluoric acid as an etching liquid to expose the gate electrode. Subsequently, the photoresist was removed in a similar manner to the patterning process of the gate electrode, thereby forming a contact hole H1.

6) Formation of Source and Drain Electrodes and Common and Signal Wires

Subsequent to the formation of the contact hole, a lift-off resist was formed, and then a film of Ti (15 nm)/Al (50 nm)/Ti (15 nm) was formed by sputtering. The resist was removed using a removing liquid, thereby forming source and drain electrodes 4-7, and common and signal wires 4-8.

Ti sputtering conditions: Ti sputtering was performed using a DC magnetron sputtering device (DC power: 400 W, sputtering gas flow rate (Ar): 14.0 sccm, and film formation pressure: 0.34 Pa).

Al sputtering conditions: Al sputtering was performed using a DC magnetron sputtering device (DC power: 400 W, sputtering gas flow rate (Ar): 14.0 sccm, and film formation pressure: 0.34 Pa).

7) Formation of Protective Insulation Film

Subsequently, a SiO₂ film having a thickness of 200 nm was formed as protective insulation film 4-10.

SiO₂ sputtering conditions: SiO₂ sputtering was performed using an RF magnetron sputtering device (RF power: 400 W, sputtering gas flow rate (Ar/O₂): 12.0/2.0 sccm, film formation pressure: 0.4 Pa).

8) Formation of Contact Hole H2

Subsequently, a patterning process by a photolitho-etching method was performed in a similar manner to the patterning process of the gate electrode, and a portion other than a portion for forming a contact hole was protected by a photoresist. Then, a hole was formed in the gate insulating film using a buffered fluoric acid as an etching liquid to expose the source and drain electrodes. Subsequently, the photoresist was removed in a similar manner to the patterning process of the gate electrode, thereby forming a contact hole H2.

9) Formation of Pixel Electrode

An ITO film for forming a pixel electrode was formed to a thickness of 50 nm on the protective insulation film, by sputtering.

ITO sputtering conditions: ITO sputtering was performed using an RF magnetron sputtering device (RF power: 200 W, sputtering gas flow rate (Ar/O₂): 14.0/0.8 sccm, film formation pressure: 0.36 Pa).

Oxalic acid was used as an etching liquid in the patterning process by the photolitho-etching method, and a pixel electrode 4-11 was thus formed.

10) Formation of Flattening Film

Subsequently, a photosensitive polyimide film was formed to a thickness of 2 μm, and the film was patterned by a photolithographic method, thereby forming a flattening film 4-12.

Conditions of an application process and a patterning process are as follows.

Film formation: spin coating at 1000 rpm for 30 sec.

Exposure: 20 sec. (using g-line rays of an extra high pressure mercury lamp, equivalent to 400 mJ/cm²)

Development: developer: NMD-3 (manufactured by TOKYO OHKA KOGYO CO., LTD.): 1 min. (immersion)+1 min. (stirring)

Rinsing: pure-water ultrasonic cleaning, 1 min. (twice)+5 min. (once)+N₂ blowing

Post baking: 120° C. for 1 h.

Through the above processes, a TFT substrate of an organic EL display was produced.

11) Production of Organic EL Device

On a TFT substrate that was subjected to oxygen plasma treatment, an organic EL layer 4-13 including a hole injection layer, a hole transport layer, a luminescent layer, a hole blocking layer, an electron transport layer, and an electron injection layer was formed. Then, a cathode 4-14 was formed on the organic EL layer using a shadow mask. Each of the above layers was formed by resistance heating vacuum evaporation.

The oxygen plasma conditions and the structure of each layer are as follows.

Oxygen plasma conditions: O₂ flow rate: 10 sccm, RF power: 200 W, processing time: 1 min.

Hole injection layer: 4,4′,4″-tris(2-naphthyl phenylamino)triphenylamine (2-TNATA), thickness: 140 nm

Hole transporting layer: N,N′-dinaphthyl-N,N′-diphenyl-[1,1′-biphenyl]-4,4′-diamine (α-NPD), thickness: 10 nm

Luminescent layer: CBP and Ir(ppy)₃ of 5 mass % with respect to CBP, thickness: 20 nm

Hole blocking layer: bis-(2-methyl-8-quinolinolate)-4-(phenylphenolate)aluminium (BAlq), thickness: 10 nm

Electron transport layer: tris(8-hydroxyquinolinato)aluminum (Alq3), thickness: 20 nm

Electron injection layer: LiF, thickness: 1 nm

Cathode (upper electrode): Al, thickness: 200 nm

An organic EL device was thus produced.

12) Sealing Process

On the TFT substrate on which the organic EL device was formed, a SiNₓ film having a thickness of 2 μm (not shown) was formed as a sealing film by plasma CVD (PECVD). Further, a protection film (obtained by vapor-depositing SiON on a PEN film to a thickness of 50 nm) was adhered to the sealing film with a thermosetting epoxy resin adhesive (90° C., 3 h.)

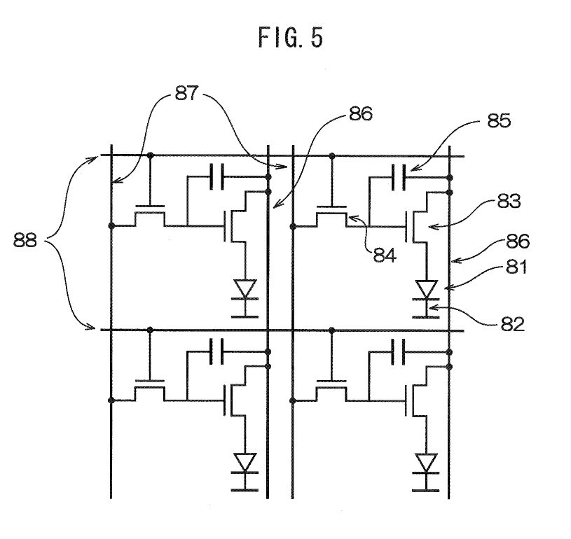

An organic EL display device was thus produced. The pixel circuit used for the organic EL display of the invention is shown in FIG. 5.

As mentioned above, the invention provides a TFT that exhibits a high degree of field-effect mobility and a high degree of on/off ratio, while maintaining stable performances with suppressed change in threshold. In particular, the TFT of the invention is useful as a flexible TFT having a flexible substrate and a display device using the same.

All publications, patent applications, and technical standards mentioned in this specification are herein incorporated by reference to the same extent as if each individual publication, patent application, or technical standard was specifically and individually indicated to be incorporated by reference.

What is claimed is:

1. A thin film field-effect transistor comprising, on a substrate, a gate electrode, a gate insulating film, an active layer comprising an oxide semiconductor, a source electrode, a drain electrode, a resistive layer comprising an oxide semiconductor and positioned between the active layer and at least one of the source electrode or the drain electrode, the resistive layer having an electric conductivity that is lower than the electric conductivity of the active layer, the electric conductivity of the active layer being from 10⁻⁴ Scm⁻¹ to less than 10² Scm⁻¹, the ratio of the electric conductivity of the active layer to the electric conductivity of the resistive layer (electric conductivity of active layer/electric conductivity of resistive layer) being from 10¹ to 10¹⁰, and at least one of the source electrode or the drain electrode comprising a layer comprising Ti or a Ti alloy positioned at the side facing the resistive layer.

2. The thin film field-effect transistor according to claim 1, wherein the active layer is in contact with the gate insulating film.

3. The thin film field-effect transistor according to claim 1, wherein the ratio of the electric conductivity of the active layer to the electric conductivity of the resistive layer (electric conductivity of active layer/electric conductivity of resistive layer) is from 10² to 10¹⁰.

4. The thin film field-effect transistor according to claim 3, wherein the ratio of the electric conductivity of the active layer to the electric conductivity of the resistive layer (electric conductivity of active layer/electric conductivity of resistive layer) is from 10² to 10⁸.

5. The thin film field-effect transistor according to claim 1, wherein the source electrode and the drain electrode include the layer comprising Ti or a Ti alloy positioned at the side facing the resistive layer.

6. The thin film field-effect transistor according to claim 1, wherein the electric conductivity of the active layer is from 10⁻¹ Sccm⁻¹ to less than 10² Scm⁻¹.

7. The thin film field-effect transistor according to claim 1, wherein at least one of the oxide semiconductor of the active layer or the oxide semiconductor of the resistive layer comprises an amorphous oxide.

8. The thin film field-effect transistor according to claim 1, wherein at least one of the oxide semiconductor of the active layer or the oxide semiconductor of the resistive layer comprises an oxide or a composite oxide of at least one selected from the group consisting of In, Ga and Zn.

9. The thin film field-effect transistor according to claim 1, wherein the substrate comprises a flexible resin substrate.

10. A display device comprising the thin film field-effect transistor according to claim 1.
